(19) United States
(12) Patent Application Publication
(10) Pub. No.: US 2025/0365006 A1
(43) Pub. Date: Nov. 27, 2025

(54) DATA TRANSMISSION METHOD AND APPARATUS

(71) Applicant: HUAWEI TECHNOLOGIES CO., LTD., Shenzhen (CN)

(72) Inventors: Yuqing DU, Shenzhen (CN); Mengyao MA, Shenzhen (CN); Min YAN, Shenzhen (CN)

(21) Appl. No.: 19/294,354

(22) Filed: Aug. 8, 2025

Related U.S. Application Data
(63) Continuation of application No. PCT/CN2023/075143, filed on Feb. 9, 2023.

(51) Int. Cl. H03M 7/32; H03M 7/30

(52) U.S. Cl. CPC H03M 7/302; H03M 7/3059

(57) ABSTRACT

A data transmission method and apparatus are disclosed, to help reduce quantization loss of data that is not uniformly distributed, thereby improving data transmission efficiency. The method includes: selecting a target data distribution model from a plurality of data distribution models based on to-be-compressed data, the plurality of data distribution models, and a first uniform quantizer; determining target compressed data based on the target data distribution model; and sending the target compressed data and first information to a receive end, where the first information includes information identifying the target data distribution model.

### CROSS-REFERENCE TO RELATED APPLICATIONS

This application is a continuation of International Application No. PCT/CN2023/075143, filed on Feb. 9, 2023, the disclosure of which is hereby incorporated by reference in its entirety.

### TECHNICAL FIELD

This application relates to the field of communication technologies, and in particular, to a data transmission method and apparatus.

### BACKGROUND

In an existing communication scenario, a large amount of data is usually transmitted from a transmit end to a receive end. For example, the transmit end transmits acquired point cloud data or artificial intelligence data to a cloud device. However, because the amount of transmitted data is relatively large, data transmission occupies a large quantity of communication resources, and communication overheads for data uploading are increased. Currently, before the data is transmitted, a quantizer is usually used to perform quantization processing on the data. To be specific, raw signals/data are/is converted into quantitative signals/data with values in a given set. The quantizer reduces the amount of transmitted data, to reduce communication overheads for data uploading.

Currently, a relatively common quantizer is used in the following method: For to-be-compressed data with a known distribution, the transmit end performs function mapping on the to-be-compressed data, so that mapped data is uniformly distributed in an interval [0, 1], and then the mapped data is compressed by using a preset uniform quantizer, and compressed data is sent to a receive end. Another method is as follows: The transmit end performs quantization processing on the to-be-compressed data by using a uniform quantizer in a given interval, to be specific, equally divides the interval based on the given interval by using a plurality of discrete values. For any piece of to-be-compressed data, a discrete value closest to the to-be-compressed data is compressed data corresponding to the to-be-compressed data, and the compressed data is sent to the receive end.

However, in reality, the distribution status of the to-be-compressed data is unknown, and most of the to-be-compressed data is not uniformly distributed. If the distribution status of the to-be-compressed data is unclear, the first method cannot be used. If the to-be-compressed data is not uniformly distributed, when the uniform quantizer in the second method is used to quantize the to-be-compressed data that is not uniformly distributed, a serious quantization loss is caused.

### SUMMARY

This application provides a data transmission method and apparatus, to help reduce quantization loss of data that is not uniformly distributed, thereby improving data transmission efficiency.

According to a first aspect, a data transmission method is provided. The method includes: determining a target data distribution model from a plurality of data distribution models based on to-be-compressed data, the plurality of data distribution models, and a first uniform quantizer, where in the plurality of data distribution models, a loss between first decompressed data corresponding to the target data distribution model and the to-be-compressed data is the smallest; determining target compressed data based on the target data distribution model; and sending the target compressed data and first information to a receive end, where the first information includes information indicating the target data distribution model.

It should be understood that the plurality of data distribution models may be pre-stored at the transmit end. For example, the data distribution model may be a Gaussian distribution model, a Laplace distribution model, a Beta distribution model, or the like. This is not limited in this embodiment.

It should be further understood that the first uniform quantizer may be pre-stored at the transmit end. The to-be-compressed data may be uniform to-be-compressed data or non-uniform to-be-compressed data, and may be to-be-compressed data with a known distribution status, or to-be-compressed data with an unclear distribution status. This is not limited in this application.

It should be understood that the transmit end may calculate a loss (also referred to as a quantization loss) between the first decompressed data corresponding to each data distribution model and the to-be-compressed data, to obtain a loss corresponding to each data distribution model, and determine a data distribution model corresponding to the smallest loss as the target data distribution model.

In the data transmission method in this embodiment, a loss corresponding to each data distribution model is calculated based on first decompressed data corresponding to each data distribution model and to-be-compressed data, a data distribution model corresponding to the smallest loss is determined as a target data distribution model, and compressed data corresponding to the target model is determined as target compressed data, so that a receive end finally receives the compressed data with the smallest loss. In addition, the target model is used to process the to-be-compressed data, so that processed data is uniformly distributed, and then a uniform quantizer is used for quantization, to avoid a quantization loss caused by compressing non-uniform to-be-compressed data by using the uniform quantizer. This method helps reduce quantization loss in a data transmission process, so that data transmission efficiency is improved. That the processed data is uniformly distributed in this application may be understood as that the processed data is approximately uniformly distributed.

With reference to the first aspect, in some implementations of the first aspect, determining the target data distribution model from the plurality of data distribution models based on the to-be-compressed data, the plurality of data distribution models, and the first uniform quantizer includes: separately performing compression processing on the to-be-compressed data based on the plurality of data distribution models and the first uniform quantizer, to obtain first compressed data corresponding to each data distribution model in the plurality of data distribution models; performing decompression processing on the first compressed data corresponding to each data distribution model, to obtain first decompressed data corresponding to each data distribution model; and determining the target data distribution model from the plurality of data distribution models based on the first decompressed data corresponding to each data distribution model and the to-be-compressed data.

With reference to the first aspect, in some implementations of the first aspect, separately performing the compression processing on the to-be-compressed data based on the plurality of data distribution models and the first uniform quantizer, to obtain the first compressed data corresponding to each data distribution model includes: separately determining, based on the to-be-compressed data, parameters corresponding to each data distribution model; separately performing mapping processing on the to-be-compressed data by using each data distribution model based on the parameters corresponding to each data distribution model, to obtain mapped data corresponding to each data distribution model, where the mapped data corresponding to each data distribution model is uniformly distributed within a preset interval range; and separately performing, by using the first uniform quantizer, quantization processing on the mapped data corresponding to each data distribution model, to obtain the first compressed data corresponding to each data distribution model.

It should be understood that the transmit end may obtain, based on the to-be-compressed data by using a mathematical method such as a Bayesian inference algorithm, the parameters corresponding to each data distribution model. For example, parameters of the Gaussian distribution model are a mean and a variance, and parameters of the Laplace distribution model are a location parameter and a scale parameter.

It should be understood that a cumulative distribution function corresponding to each data distribution model may be obtained based on the parameters corresponding to each data distribution model, mapping processing is performed on the to-be-compressed data by using the cumulative distribution function corresponding to each data distribution model, to obtain the mapped data, and the mapped data is uniformly distributed in the preset interval range. For example, the preset interval range is [0, 1].

In the method in this embodiment, mapping processing is performed on the to-be-compressed data by using the cumulative distribution function corresponding to each data distribution model, so that the mapped data is uniformly distributed in the preset interval range, and then the mapped data is quantized by using the first uniform quantizer, to avoid a serious quantization loss caused by compressing the non-uniform to-be-compressed data by using the uniform quantizer, thereby helping reduce quantization loss in a data transmission process.

With reference to the first aspect, in some implementations of the first aspect, the first information further includes information indicating parameters corresponding to the target data distribution model.

With reference to the first aspect, in some implementations of the first aspect, separately performing the mapping processing on the to-be-compressed data by using each data distribution model based on the parameters corresponding to each data distribution model, to obtain the mapped data corresponding to each data distribution model, further includes: performing preliminary processing on the to-be-compressed data, to obtain preliminarily processed data, where the preliminarily processed data is within the preset interval range, and the preliminary processing includes translation processing and/or stretching processing; and separately performing the mapping processing on the preliminarily processed data by using each data distribution model based on the parameters corresponding to each data distribution model, to obtain the mapped data corresponding to each data distribution model.

It should be understood that the preset interval range meets domains of the cumulative distribution functions corresponding to the plurality of data distribution models. For example, the preset interval range may be [0, 1].

It should be understood that, in a possible implementation, the preliminary processing may be translation processing. In another possible implementation, the preliminary processing may be stretching processing. In another possible implementation, the preliminary processing may be first translation processing and then stretching processing. In still another possible implementation, the preliminary processing may be first stretching processing and then translation processing. It should be further understood that, when preliminary processing is performed on the to-be-compressed data, when the target compressed data and the first information are sent to the receive end, parameter information used in the preliminary processing process further needs to be sent to the receive end, so that the parameter information is used when the target compressed data is decompressed subsequently.

In the method in this embodiment, preliminary processing is performed on the to-be-compressed data, so that the preliminarily processed data is within the preset interval range. This avoids a case in which subsequent mapping processing cannot be performed because the to-be-compressed data does not meet domains of the cumulative distribution functions corresponding to the data distribution models. In this embodiment, data processing efficiency of the transmit end is improved, and data transmission efficiency between the transmit end and the receive end is further improved.

With reference to the first aspect, in some implementations of the first aspect, performing the decompression processing on the first compressed data corresponding to each data distribution model, to obtain the first decompressed data corresponding to each data distribution model includes: separately performing, by using each data distribution model based on the parameters corresponding to each data distribution model, inverse processing on the first compressed data corresponding to each data distribution model, to obtain the first decompressed data corresponding to each data distribution model, where the inverse processing includes inverse translation processing and/or inverse stretching processing, and inverse mapping processing.

It should be understood that the inverse processing may be in the following several cases: In a possible implementation, if translation processing is first performed and then mapping processing is performed on the to-be-compressed data, correspondingly, the inverse processing is first performing inverse mapping processing and then performing inverse translation processing. In another possible implementation, if stretching processing is first performed and then mapping processing is performed on the to-be-compressed data, correspondingly, the inverse processing is first performing inverse mapping processing and then performing inverse stretching processing. In another possible implementation, if stretching processing is first performed, then translation processing is performed, and finally mapping processing is performed on the to-be-compressed data, correspondingly, the inverse processing is first performing inverse mapping processing, and then performing inverse translation processing and inverse stretching processing. In still another possible implementation, if translation processing is first performed, then stretching processing is performed, and finally mapping processing is performed on the to-be-compressed data, correspondingly, the inverse processing is first performing inverse mapping processing, and then performing inverse stretching processing and inverse translation processing. It should be understood that a formula used during inverse stretching processing is a mathematical inverse operation of a formula used during stretching processing, and a formula used during inverse translation processing is a mathematical inverse operation of a formula used during translation processing.

With reference to the first aspect, in some implementations of the first aspect, determining the target compressed data based on the target data distribution model includes: when a difference obtained by subtracting the loss between the first decompressed data corresponding to the target data distribution model and the to-be-compressed data from a loss between second decompressed data and the to-be-compressed data is greater than 0 and greater than or equal to a preset threshold, determining the first compressed data corresponding to the target data distribution model as the target compressed data, where the second decompressed data is obtained by performing decompression processing on second compressed data, the second compressed data is obtained by performing compression processing on the to-be-compressed data based on a second uniform quantizer, and the second uniform quantizer has same compression precision as the first uniform quantizer.

It should be understood that the transmit end may generate the second uniform quantizer in a given interval based on the to-be-compressed data. The given interval is determined by a largest value and a smallest value in the to-be-compressed data.

With reference to the first aspect, in some implementations of the first aspect, determining the target compressed data based on the target data distribution model includes: when the difference is less than 0 or the difference is greater than 0 and less than the preset threshold, adjusting the parameters of the target data distribution model based on prior parameters; and performing compression processing on the to-be-compressed data by using the target data distribution model based on the adjusted parameters, to obtain the target compressed data.

It should be understood that the prior parameters are sent by the receive end. It should be further understood that after adjusting the parameters corresponding to the target data distribution model, the transmit end sends, to the receive end, the adjusted parameters corresponding to the target data distribution model.

With reference to the first aspect, in some implementations of the first aspect, the method further includes: sending second information to the receive end, where the second information indicates parameters of the to-be-compressed data and the target data distribution model; and receiving third information from the receive end, where the third information includes the prior parameters.

It should be understood that the parameters of the to-be-compressed data may be location information of the to-be-compressed data.

With reference to the first aspect, in some implementations of the first aspect, before separately performing the compression processing on the to-be-compressed data based on the plurality of data distribution models and the first uniform quantizer, the method further includes: sending fourth information to the receive end, where the fourth information is used to query compression precision of the to-be-compressed data; and receiving fifth information from the receive end, where the fifth information indicates the compression precision of the to-be-compressed data.

It should be understood that the transmit end sends the fourth information to the receive end, where the fourth information carries a type and a data amount that are of the to-be-compressed data. Correspondingly, the receive end receives the fourth information, queries, based on the type and the data amount that are of the to-be-compressed data and that are carried in the fourth information, the compression precision corresponding to the data of the type and the data amount, and sends the compression precision to the transmit end.

According to a second aspect, a data transmission method is provided, where the method includes: receiving target compressed data and first information from a transmit end, where the target compressed data is obtained by performing compression processing on to-be-compressed data by using a target data distribution model and a first uniform quantizer, and the first information includes information indicating the target data distribution model; and performing decompression processing on the target compressed data based on the first information, to obtain target decompressed data.

With reference to the second aspect, in some implementations of the second aspect, the first information further includes information indicating parameters corresponding to the target data distribution model.

With reference to the second aspect, in some implementations of the second aspect, performing the decompression processing on the target compressed data based on the first information, to obtain the target decompressed data includes: performing inverse processing on the target compressed data by using the target data distribution model based on the parameters corresponding to the target data distribution model, to obtain the target decompressed data, where the inverse processing includes inverse translation processing and/or inverse stretching processing, and inverse mapping processing.

With reference to the second aspect, in some implementations of the second aspect, before receiving the target compressed data and the first information from the transmit end, the method further includes: receiving second information from the transmit end, where the second information indicates parameters of the to-be-compressed data and the target data distribution model; and sending third information to the transmit end, where the third information includes prior parameters of the target data distribution model.

With reference to the second aspect, in some implementations of the second aspect, before receiving the target compressed data and the first information from the transmit end, the method further includes: receiving fourth information from the transmit end, where the fourth information is used to query compression precision of the to-be-compressed data; and sending fifth information to the transmit end, where the fifth information indicates the compression precision of the to-be-compressed data.

According to a third aspect, a data transmission apparatus is provided, configured to perform the method in any possible implementation in the foregoing aspects. Specifically, the data transmission apparatus includes modules configured to perform the method in any possible implementation in the foregoing aspects.

In a design, the data transmission apparatus may include a one-to-one corresponding module that performs the method/operation/step/action described in the foregoing aspects. The module may be a hardware circuit, or software, or may be implemented by a hardware circuit in combination with software.

In another design, the data transmission apparatus is a communication chip. The communication chip may include an input circuit or interface configured to send information or data, and an output circuit or interface configured to receive information or data.

In another design, the data transmission apparatus may be a communication device. The communication device may include a transmitter configured to send information or data, and a receiver configured to receive information or data.

According to a fourth aspect, another data transmission apparatus is provided, including a processor and a memory. The processor is configured to read instructions stored in the memory, and may receive a signal by using a receiver and transmit a signal by using a transmitter, to perform the method in any possible implementation in the foregoing first aspect or second aspect.

Optionally, there are one or more processors, and there are one or more memories.

Optionally, the memory and the processor may be integrated together, or the memory and the processor may be separately disposed.

In a specific implementation process, the memory may be a non-transitory memory, such as a read-only memory (ROM). The memory and the processor may be integrated into one chip, or may be separately disposed in different chips. A type of the memory and a manner in which the memory and the processor are disposed are not limited in this embodiment.

It should be understood that, a related data exchange process such as sending of indication information may be a process of outputting the indication information from the processor, and receiving of capability information may be a process of receiving the input capability information by the processor. Specifically, data output by the processor may be output to the transmitter, and input data received by the processor may be from the receiver. The transmitter and the receiver may be collectively referred to as a transceiver.

The data transmission apparatus in the fourth aspect may be a chip. The processor may be implemented by using hardware or may be implemented by using software. When implemented by using hardware, the processor may be a logic circuit, an integrated circuit, or the like. When implemented by using software, the processor may be a general-purpose processor, and is implemented by reading software code stored in the memory. The memory may be integrated into the processor or may exist independent of the processor.

According to a fifth aspect, a computer-readable storage medium is provided. The computer-readable storage medium stores a computer program (which may also be referred to as code or an instruction). When the computer program is run on a computer, the computer is enabled to perform the method in any possible implementation in the foregoing first aspect or second aspect.

According to a sixth aspect, a computer program product is provided. The computer program product includes a computer program (which may also be referred to as code or an instruction). When the computer program is run, a computer is enabled to perform the method in any possible implementation in the foregoing first aspect or second aspect.

### BRIEF DESCRIPTION OF DRAWINGS

FIG. 1 is a diagram of an example application scenario according to an embodiment of this application;

FIG. 2 is a schematic flowchart of an example data transmission method according to an embodiment of this application;

FIG. 3A and FIG. 3B show a schematic flowchart of another example data transmission method according to an embodiment of this application;

FIG. 4A, FIG. 4B, FIG. 4C, and FIG. 4D show a schematic flowchart of another example data transmission method according to an embodiment of this application;

FIG. 5 is a diagram of example target compressed data and parameter information according to an embodiment of this application;

FIG. 6 is a block diagram of an example data transmission apparatus according to an embodiment of this application; and

FIG. 7 is a block diagram of another example data transmission apparatus according to an embodiment of this application.

### DESCRIPTION OF EMBODIMENTS

The following describes technical solutions in this application with reference to the accompanying drawings.

In embodiments of this application, terms such as “first” and “second” are used to distinguish between same items or similar items having basically same functions and roles. For example, a first chip and a second chip are merely used to distinguish between different chips, and a sequence is not limited therebetween. A person skilled in the art may understand that the terms such as “first” and “second” do not limit a quantity or an execution sequence, and the terms such as “first” and “second” do not indicate a definite difference.

It should be noted that, in embodiments of this application, the word “example” or “for example” or the like represents giving an example, an illustration, or a description. Any embodiment or design scheme described as an “example” or “for example” in present disclosure should not be explained as being more preferred or having more advantages than another embodiment or design scheme. Exactly, use of the word “example”, “for example”, or the like is intended to present a related concept in a specific manner.

In embodiments of this application, “at least one” means one or more, and “a plurality of” means two or more. “And/or” describes an association relationship between associated objects, and represents that any one of three relationships may exist. For example, A and/or B may represent the following cases: Only A exists, both A and B exist, or only B exists, where A and B may be singular or plural. The character “/” generally indicates an “or” relationship between the associated objects. “At least one of the following items” or its similar expressions mean any combination of these items, including any combination of a single item or a plurality of items. For example, at least one of a, b, or c may represent a, b, c, a-b, a-c, b-c, or a-b-c, where a, b, and c may be singular or plural.

The technical solutions in embodiments of this application may be applied to various communication systems, such as a long term evolution (LTE) system, an LTE frequency division duplex (FDD) system, LTE time division duplex (TDD) system, a universal mobile telecommunications system (UMTS), a 5th generation (5G) system, a new radio (NR) system, another evolved communication system, or the like.

A terminal device in embodiments of this application may also be referred to as user equipment (UE), a mobile station (MS), a mobile terminal (MT), an access terminal, a subscriber unit, a subscriber station, a mobile station, a remote station, a remote terminal, a mobile device, a user terminal, a terminal, a wireless communication device, a user agent, a user apparatus, or the like.

The terminal device may be a device that provides voice/data connectivity for a user, for example, a handheld device or a vehicle-mounted device that has a wireless connection function. Currently, some examples of the terminal may be: a mobile phone, a tablet computer, a notebook computer, a palmtop computer, a mobile Internet device (MID), a wearable device, a virtual reality (VR) device, an augmented reality (AR) device, a wireless terminal in industrial control, a wireless terminal in self-driving, a wireless terminal in remote medical surgery, a wireless terminal in a smart grid, a wireless terminal in transportation safety, a wireless terminal in a smart city, a wireless terminal in a smart home, a cellular phone, a cordless phone, a session initiation protocol (SIP) phone, a wireless local loop (WLL) station, a personal digital assistant (PDA), a handheld device having a wireless communication function, a computing device or another processing device connected to a wireless modem, a vehicle-mounted device, a wearable device, a terminal device in a 5G network, a terminal device in a future evolved public land mobile network (PLMN), or the like. This is not limited in embodiments of this application.

By way of example instead of limitation, in embodiments of this application, the terminal device may alternatively be a wearable device. The wearable device may also be referred to as a wearable intelligent device, and is a general term of a wearable device that is intelligently designed and developed for daily wear by using a wearable technology, for example, glasses, gloves, a watch, clothing, and shoes. The wearable device is a portable device that is directly worn on the body or integrated into clothes or an accessory of a user. The wearable device is not only a hardware device, but also implements a powerful function through software support, data exchange, and cloud interaction. In a broad sense, wearable intelligent devices include full-featured and large-sized devices that can implement all or a part of functions without depending on smartphones, for example, smart watches or smart glasses, and include devices that focus on only one type of application function and need to collaboratively work with other devices such as smartphones, for example, various smart bands or smart jewelry for monitoring physical signs.

In addition, in embodiments of this application, the terminal device may alternatively be a terminal device in an Internet of Things (IoT) system. The IoT is an important part of future development of information technologies, and a main technical feature of the IoT is to connect things to a network by using a communication technology, to implement an intelligent network for human-machine interconnection or interconnection between things.

In addition, a network device in embodiments of this application may be a device configured to communicate with the terminal device, and the network device may be an evolved NodeB (eNB or eNodeB) in an LTE system, or may be a wireless controller in a cloud radio access network (CRAN) scenario, or the network device may be a relay station, an access point, a vehicle-mounted device, a wearable device, a network device in a future 5G network, a network device in a future evolved PLMN network, or the like. This is not limited in embodiments of this application. For example, the network device may be a gNB or a transmission point (TRP or TP) in an NR system, one antenna panel or a group of (including a plurality of antenna panels) antenna panels of a base station in a 5G system, or a network node forming the gNB or the transmission point, such as a baseband unit (BBU) or a distributed unit (DU).

In some deployments, the gNB may include a central unit (CU) and a DU. The gNB may further include a radio unit (RU). The CU implements some functions of the gNB, and the DU implements some functions of the gNB. For example, the CU implements functions of a radio resource control (RRC) layer and a packet data convergence protocol (PDCP) layer; and the DU implements functions of a radio link control (RLC) layer, a media access control (MAC) layer, and a physical (PHY) layer. Information at the RRC layer eventually becomes information at the PHY layer, or is converted from the information at the PHY layer. Therefore, in this architecture, higher layer signaling such as RRC layer signaling may also be considered as being sent by the DU or sent by the DU and the CU. It may be understood that the network device may be a CU node, a DU node, or a device including a CU node and a DU node. In addition, the CU may be classified into a network device in an access network (RAN), or the CU may be classified into a network device in a core network (CN). This is not limited in this application.

Alternatively, the network device may be a general term of all devices at a network end. For example, when a plurality of TRPs are used to transmit data to the terminal device, the plurality of TRPs may be collectively referred to as the network device.

In embodiments of this application, the terminal device or the network device includes a hardware layer, an operating system layer running above the hardware layer, and an application layer running above the operating system layer. The hardware layer includes hardware such as a central processing unit (CPU), a memory management unit (MMU), and a memory (also referred to as a main memory). The operating system may be any one or more types of computer operating systems that implement service processing through a process, for example, a Linux operating system, a Unix operating system, an Android operating system, an iOS operating system, or a Windows operating system. The application layer includes applications such as a browser, an address book, word processing software, and instant messaging software. In addition, a specific structure of an execution body of a method provided in embodiments of this application is not particularly limited in embodiments of this application, provided that a program that records code of the method provided in embodiments of this application can be run to perform communication according to the method provided in embodiments of this application. For example, the execution body of the method provided in embodiments of this application may be the terminal device or the network device, or a functional module that can invoke and execute the program in the terminal device or the network device.

In addition, aspects or features of this application may be implemented as a method, an apparatus, or a product that uses standard programming and/or engineering technologies. The term “product” used in present disclosure covers a computer program that can be accessed from any computer-readable component, carrier or medium. For example, the computer-readable medium may include but is not limited to: a magnetic storage component (for example, a hard disk, a floppy disk, or a magnetic tape), an optical disc (for example, a compact disc (CD), or a digital versatile disc (DVD)), a smart card, and a flash memory component (for example, an erasable programmable read-only memory (EPROM), a card, a stick, or a key drive). In addition, various storage media described in this specification may represent one or more devices and/or other machine-readable media that are configured to store information. The term “machine-readable media” may include but is not limited to a wireless channel, and various other media that can store, include, and/or carry instructions and/or data.

In an existing communication scenario, a large amount of data is usually transmitted from a transmit end to a receive end. For example, the transmit end transmits acquired point cloud data or artificial intelligence data to a cloud device. However, because the amount of transmitted data is relatively large, a large quantity of communication resources are occupied during transmission, and communication overheads for data uploading are increased. Currently, before the data is transmitted, a quantizer is usually used to perform quantization processing on the data. To be specific, raw signals/data are/is converted into quantitative signals/data with values in a given set. The quantizer reduces the amount of transmitted data, to reduce communication overheads for data uploading.

For ease of understanding of this application, the following describes an application scenario with reference to FIG. 1.

FIG. 1 is a diagram of an example application scenario 100 according to an embodiment of this application. The application scenario includes a transmit end 101 and a receive end 102. The transmit end 101 may compress to-be-compressed data by using a quantizer, to obtain compressed data, and send the compressed data to the receive end 102. Correspondingly, after receiving the compressed data, the receive end 102 may decompress the compressed data.

In a possible implementation, the transmit end may be the foregoing terminal device, and the receive end may be the foregoing network device. In another possible implementation, the transmit end may be the foregoing network device, and the receive end may be the foregoing terminal device.

It should be understood that the transmit end 101 may be specifically a device having a capability of compressing data by using the quantizer. The receive end 102 is specifically a device having a data decompression capability. It should be further understood that in the foregoing application scenario, there may be one or more receive ends. This is not limited in embodiments of this application.

The following describes quantizers that are commonly used at present.

In a first method, the transmit end maps the to-be-compressed data by using a cumulative distribution function (CDF) corresponding to the to-be-compressed data with a known distribution (when distribution of the to-be-compressed data is known, the cumulative distribution function corresponding to the to-be-compressed data with known distribution is known), to obtain mapped data, where the mapped data is in an interval [0, 1], and the mapped data is uniformly distributed in the interval [0, 1]. Then, the transmit end compresses the mapped data by using a preset uniform quantizer, to obtain compressed data, and sends the compressed data to the receiving device. Correspondingly, the receiving device receives the compressed data, and decompresses the compressed data by using an inverse function of the CDF function. In another method, the transmit end performs compression processing on the to-be-compressed data by using a uniform quantizer in a given interval, to be specific, equally divides the interval based on the given interval by using a plurality of discrete values. For any piece of to-be-compressed data, a discrete value closest to the to-be-compressed data is compressed data corresponding to the to-be-compressed data, and the compressed data is sent to the receiving device.

However, in reality, the distribution status of the to-be-compressed data is unknown, and most of the to-be-compressed data is not uniformly distributed. If the distribution status of the to-be-compressed data is unclear, the first method cannot be used. If the raw data is not uniformly distributed, when the uniform quantizer in the second method is used to quantize the raw data that is not uniformly distributed, a serious quantization loss is caused, a quantization result finally obtained by the receive end is inaccurate, and data transmission efficiency is also reduced.

In view of this, embodiments of this application provide a data transmission method and apparatus. A loss corresponding to each data distribution model is calculated based on first decompressed data corresponding to each data distribution model and to-be-compressed data, a data distribution model corresponding to the smallest loss is determined as a target data distribution model, and compressed data corresponding to the target model is determined as target compressed data, so that a receive end finally receives the compressed data with the smallest loss. In addition, the target model is used to process the to-be-compressed data, so that processed data is uniformly distributed, and then a uniform quantizer is used for quantization, to avoid a quantization loss caused by compressing non-uniform to-be-compressed data by using the uniform quantizer. This method helps reduce quantization loss in a data transmission process, so that data transmission efficiency is improved.

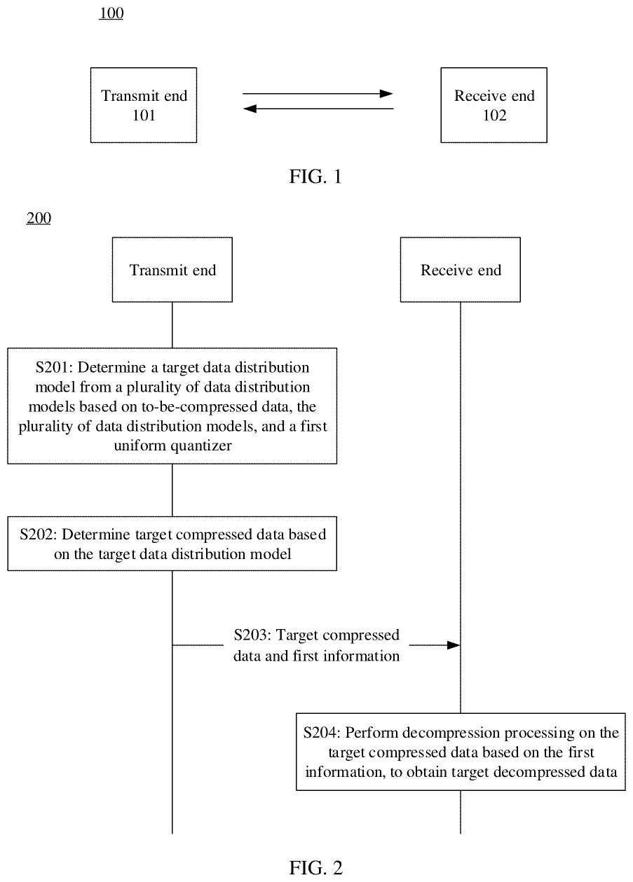

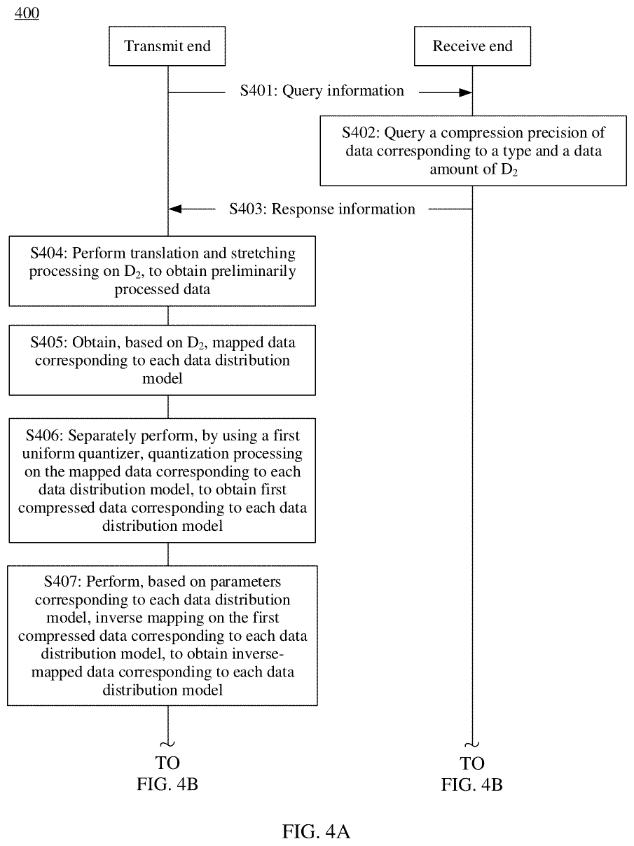

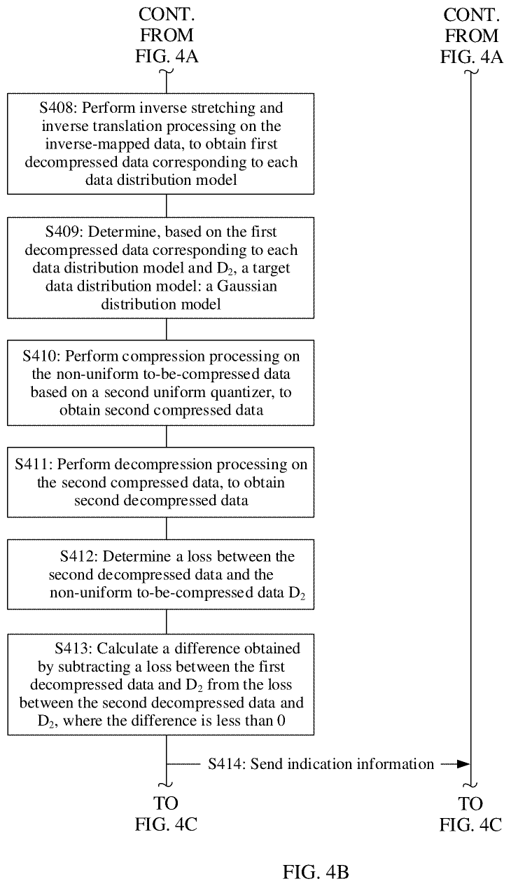

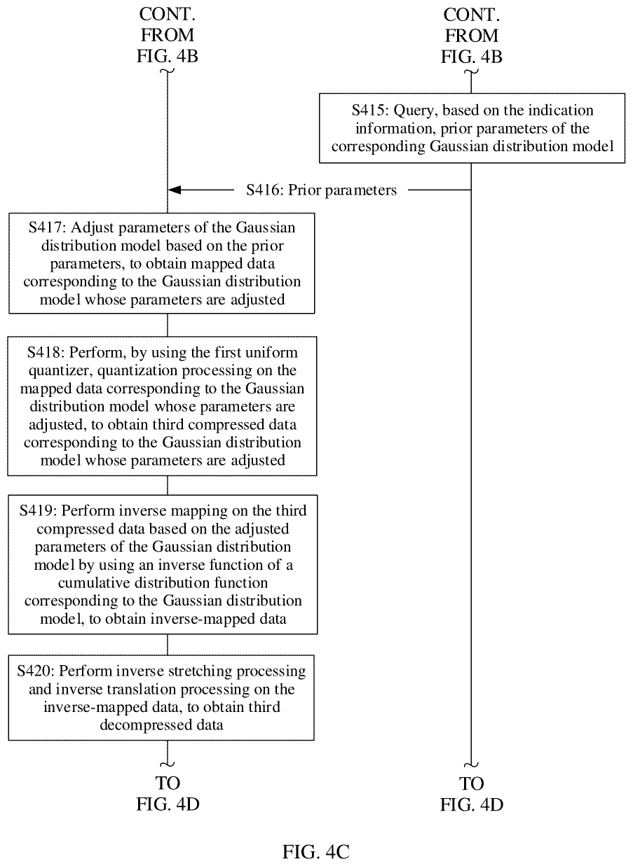

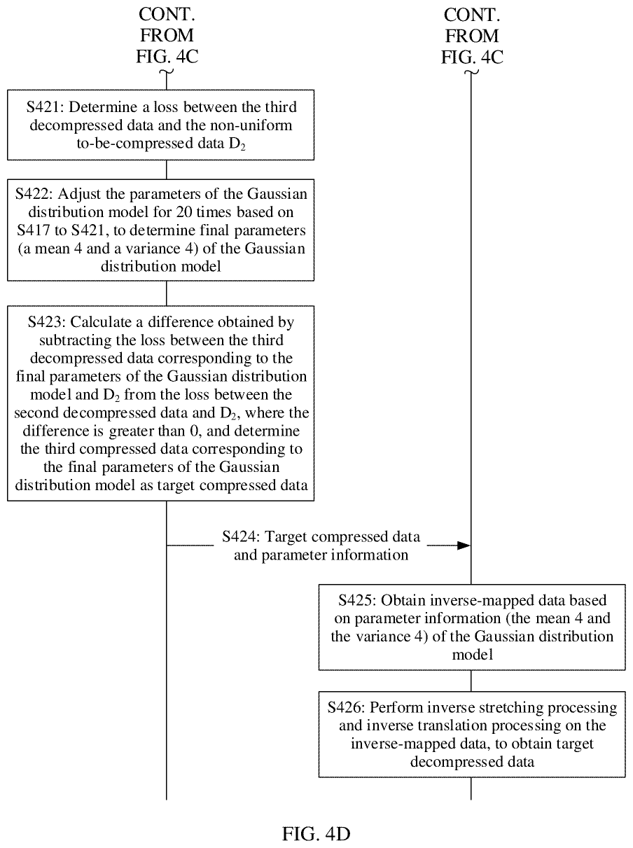

The following describes, with reference to FIG. 2 to FIG. 4A, FIG. 4B, FIG. 4C, and FIG. 4D, the data transmission methods provided in embodiments of this application.

FIG. 2 is a schematic flowchart of an example data transmission method 200 according to an embodiment of this application. The method 200 may be applied to the foregoing application scenario 100. The method 200 includes the following steps.

S201: A transmit end determines a target data distribution model from a plurality of data distribution models based on to-be-compressed data, the plurality of data distribution models, and a first uniform quantizer, where in the plurality of data distribution models, a loss between first decompressed data corresponding to the target data distribution model and the to-be-compressed data is the smallest.

It should be understood that the plurality of data distribution models may be pre-stored at the transmit end. For example, the data distribution model may be a Gaussian distribution model, a Laplace distribution model, a Beta distribution model, or the like. This is not limited in this embodiment of this application.

It should be further understood that the first uniform quantizer may be pre-stored at the transmit end. The to-be-compressed data may be uniform to-be-compressed data or non-uniform to-be-compressed data, and may be to-be-compressed data with known a distribution status, or to-be-compressed data with an unclear distribution status. This is not limited in this application. For example, the to-be-compressed data is artificial intelligence data, and the to-be-compressed data is point cloud data.

For example, the transmit end performs mapping processing on the to-be-compressed data by using a function corresponding to the Gaussian distribution model, to obtain mapped data, where the mapped data is uniformly distributed data, and then performs compression processing on the mapped data by using the first uniform quantizer, to obtain first compressed data corresponding to the Gaussian distribution model. That the mapped data is uniformly distributed data may be understood as that the mapped data is approximately uniformly distributed data.

S202: The transmit end determines target compressed data based on the target data distribution model.

It should be understood that the transmit end determines the first compressed data corresponding to the target data distribution model in S201 as the target compressed data.

S203: The transmit end sends the target compressed data and first information to a receive end, where the first information includes information indicating the target data distribution model. Correspondingly, the receive end receives the target compressed data and the first information from the transmit end.

For example, the first information may be the Gaussian distribution model.

S204: The receive end performs decompression processing on the target compressed data based on the first information, to obtain target decompressed data.

For example, the first information is the Gaussian distribution model, and the receive end performs inverse mapping (that is, decompression processing) on the target compressed data by using an inverse function of a cumulative distribution function corresponding to the Gaussian distribution model, to obtain the target decompressed data.

In the data transmission method in this embodiment, a loss corresponding to each data distribution model is calculated based on first decompressed data corresponding to each data distribution model and to-be-compressed data, a data distribution model corresponding to the smallest loss is determined as a target data distribution model, and compressed data corresponding to the target model is determined as target compressed data, so that a receive end finally receives the compressed data with the smallest loss. In addition, the target model is used to process the to-be-compressed data, so that processed data is uniformly distributed, and then a uniform quantizer is used for quantization, to avoid a quantization loss caused by compressing non-uniform to-be-compressed data by using the uniform quantizer. This method helps reduce quantization loss in a data transmission process, so that data transmission efficiency is improved. That the processed data is uniformly distributed in present disclosure may be understood as that the processed data is approximately uniformly distributed.

It should be understood that sequence numbers of the foregoing processes do not mean execution sequences, and the execution sequences of the processes should be determined based on functions and internal logic of the processes.

Optionally, the transmit end sends, to the receive end, a code word corresponding to the target compressed data.

For example, the target compressed data is 0.2, the code word corresponding to the target compressed data is 2, and the transmit end sends 2 to the receive end. It should be understood that there is a correspondence between the code word and the target compressed data. The transmit end may obtain, based on the target compressed data by using an entropy coding algorithm, for example, a lossless compression algorithm (lempel-ziv 77, LZ77) or a chain compression algorithm (lempel-ziv markov chain algorithm, LZMA), the code word corresponding to the target compressed data, and the code word and the target compressed data that have the correspondence are recorded on a codebook. Both the transmit end and the receive end have the codebook. The receive end may query, by using the codebook, that data corresponding to the code word 2 is 0.2, and then restore the target compressed data 0.2. The entropy encoding algorithm is not limited in this application.

In present disclosure, the code word is sent to the receive end, so that a data amount of transmission can be further reduced, to improve data transmission efficiency.

In an optional embodiment, determining the target data distribution model from the plurality of data distribution models based on the to-be-compressed data, the plurality of data distribution models, and the first uniform quantizer in S201 includes: separately performing compression processing on the to-be-compressed data based on the plurality of data distribution models and the first uniform quantizer, to obtain first compressed data corresponding to each data distribution model in the plurality of data distribution models; performing decompression processing on the first compressed data corresponding to each data distribution model, to obtain first decompressed data corresponding to each data distribution model; and determining the target data distribution model from the plurality of data distribution models based on the first decompressed data corresponding to each data distribution model and the to-be-compressed data.

For example, the transmit end performs mapping processing on the to-be-compressed data by using a function corresponding to the Gaussian distribution model, to obtain mapped data, where the mapped data is uniformly distributed data, and then performs compression processing on the mapped data by using the first uniform quantizer, to obtain first compressed data corresponding to the Gaussian distribution model.

For example, the transmit end performs, by using an inverse function of the function corresponding to the Gaussian distribution model, inverse mapping (that is, decompression processing) on the first compressed data corresponding to the Gaussian distribution model, to obtain first decompressed data corresponding to the Gaussian distribution model.

It should be understood that the transmit end may calculate a loss (also referred to as a quantization loss) between the first decompressed data corresponding to each data distribution model and the to-be-compressed data, to obtain a loss corresponding to each data distribution model, and determine a data distribution model corresponding to the smallest loss as the target data distribution model. For example, if the loss corresponding to the Gaussian distribution model is 0.00021, and the loss corresponding to the Laplace distribution model is 0.00017, the Laplace distribution model is the target data distribution model.

For example, the first decompressed data is S₁, S₂, S₃, and S₄, and the to-be-compressed data is Y₁, Y₂, Y₃, and Y₄. The loss between the first decompressed data and the to-be-compressed data may be calculated by using the following formula:

$$Loss = \frac{{( {S}_{1} - {Y}_{1} )}^{2} + {( {S}_{2} - {Y}_{2} )}^{2} + {( {S}_{3} - {Y}_{3} )}^{2} + {( {S}_{4} - {Y}_{4} )}^{2}}{4} .$$

In an optional embodiment, separately performing the compression processing on the to-be-compressed data based on the plurality of data distribution models and the first uniform quantizer, to obtain the first compressed data corresponding to each data distribution model includes: separately determining, based on the to-be-compressed data, parameters corresponding to each data distribution model; separately performing mapping processing on the to-be-compressed data by using each data distribution model based on the parameters corresponding to each data distribution model, to obtain mapped data corresponding to each data distribution model, where the mapped data corresponding to each data distribution model is uniformly distributed within a preset interval range; and separately performing, by using the first uniform quantizer, quantization processing on the mapped data corresponding to each data distribution model, to obtain the first compressed data corresponding to each data distribution model.

It should be understood that the transmit end may obtain, based on the to-be-compressed data by using a mathematical method such as a Bayesian inference algorithm, the parameters corresponding to each data distribution model. For example, parameters of the Gaussian distribution model are a mean and a variance, and parameters of the Laplace distribution model are a location parameter and a scale parameter.

It should be understood that a cumulative distribution function corresponding to each data distribution model may be obtained based on the parameters corresponding to each data distribution model, mapping processing is performed on the to-be-compressed data by using the cumulative distribution function corresponding to each data distribution model, to obtain the mapped data, and the mapped data is uniformly distributed in the preset interval range. For example, the preset interval range is [0, 1]. It should be further understood that, that the mapped data is uniformly distributed in the preset interval range may be understood as that the mapped data is approximately uniformly distributed in the preset interval range.

For example, the cumulative distribution function corresponding to the Gaussian distribution model is as follows:

$$F ( x : μ , σ ) = \frac{1}{σ \sqrt{2 π}} {\int }_{- ∞}^{x} exp ( - \frac{{( t - μ )}^{2}}{2 {σ}^{2}} ) dt$$

μ is the mean corresponding to the Gaussian distribution model, σ is the variance corresponding to the Gaussian distribution model, and x is the to-be-compressed data.

There are two methods for determining the cumulative distribution function corresponding to each data distribution model. In a possible implementation, the cumulative distribution function corresponding to each data distribution model may be directly obtained based on the parameters corresponding to each data distribution model. In another possible implementation, based on the parameters corresponding to each data distribution model, a probability density function that corresponds to each data distribution model and that is shown in the following may be obtained, and then upper limit integration is performed on each probability density function from negative infinity to x, to obtain the corresponding cumulative distribution function.

$$f ( x : μ , σ ) = \frac{1}{σ \sqrt{2 π}} exp ( - \frac{{( x - μ )}^{2}}{2 {σ}^{2}} )$$

In the foregoing method, mapping processing is performed on the to-be-compressed data by using the cumulative distribution function corresponding to each data distribution model, so that the mapped data is uniformly distributed in the preset interval range, and then the mapped data is quantized by using the first uniform quantizer, to avoid a serious quantization loss caused by compressing the non-uniform to-be-compressed data by using the uniform quantizer, thereby helping reduce quantization loss in a data transmission process.

Optionally, the first information further includes information indicating parameters corresponding to the target data distribution model.

For example, the target data distribution model is the Gaussian distribution model, and information about the parameters corresponding to the Gaussian distribution model is as follows: mean: 0; and variance: 0.2.

Optionally, separately performing the mapping processing on the to-be-compressed data by using each data distribution model based on the parameters corresponding to each data distribution model, to obtain the mapped data corresponding to each data distribution model, further includes: performing preliminary processing on the to-be-compressed data, to obtain preliminarily processed data, where the preliminarily processed data is within the preset interval range, and the preliminary processing includes translation processing and/or stretching processing; and separately performing the mapping processing on the preliminarily processed data by using each data distribution model based on the parameters corresponding to each data distribution model, to obtain the mapped data corresponding to each data distribution model.

It should be understood that the preset interval range meets domains of the cumulative distribution functions corresponding to the plurality of data distribution models. For example, the preset interval range may be [0, 1].

It should be understood that, in a possible implementation, the preliminary processing may be translation processing. In another possible implementation, the preliminary processing may be stretching processing. In still another possible implementation, the preliminary processing may be first translation processing and then stretching processing. In yet another possible implementation, the preliminary processing may be first stretching processing and then translation processing. It should be further understood that, when preliminary processing is performed on the to-be-compressed data, when the target compressed data and the first information are sent to the receive end, parameter information used in the preliminary processing process further needs to be sent to the receive end, so that the parameter information is used when the target compressed data is decompressed subsequently.

For example, in the preliminary processing, translation processing may be first performed, and then stretching processing is performed. The transmit end performs translation processing on the to-be-compressed data by using the following formula, to obtain translated data:

$${\mathring{S}}_{i} = {S}_{i} + \vert min {S}_{i} \vert$$

Sᵢ an i^{th} piece of data in the to-be-compressed data, i is an index of the to-be-compressed data, |min Sᵢ| is an absolute value of the smallest piece of data in the to-be-compressed data, and S̊ᵢ is data obtained after the i^{th} piece of data in the to-be-compressed data is translated.

The transmit end performs stretching processing on the translated data by using the following formula, to obtain the preliminarily processed data:

$${x}_{i} = \frac{{\mathring{S}}_{i}}{max \vert {\mathring{S}}_{i} \vert}$$

S̊ᵢ is the data obtained after the i^{th} piece of data in the to-be-compressed data is translated, max|S̊ᵢ| is data with a largest absolute value in the translated data corresponding to the to-be-compressed data, and xᵢ is data obtained after the i^{th} piece of data in the to-be-compressed data is preliminarily processed.

When the target compressed data and the first information are sent to the receive end, |min Sᵢ| and max(Sᵢ+|min Sᵢ|) further need to be sent to the receive end.

In the foregoing method, preliminary processing is performed on the to-be-compressed data, so that the preliminarily processed data is within the preset interval range. This avoids a case in which subsequent mapping processing cannot be performed because the to-be-compressed data does not meet domains of the cumulative distribution functions corresponding to the data distribution models. In this embodiment, data processing efficiency of the transmit end is improved, and data transmission efficiency between the transmit end and the receive end is further improved.

In an optional embodiment, performing the decompression processing on the first compressed data corresponding to each data distribution model, to obtain the first decompressed data corresponding to each data distribution model includes: separately performing, by using each data distribution model based on the parameters corresponding to each data distribution model, inverse processing on the first compressed data corresponding to each data distribution model, to obtain the first decompressed data corresponding to each data distribution model, where the inverse processing includes inverse translation processing and/or inverse stretching processing, and inverse mapping processing.

It should be understood that the inverse processing may be in the following several cases: In a possible implementation, if translation processing is first performed and then mapping processing is performed on the to-be-compressed data, correspondingly, the inverse processing is first performing inverse mapping processing and then performing inverse translation processing. In another possible implementation, if stretching processing is first performed and then mapping processing is performed on the to-be-compressed data, correspondingly, the inverse processing is first performing inverse mapping processing and then performing inverse stretching processing. In another possible implementation, if stretching processing is first performed, then translation processing is performed, and finally mapping processing is performed on the to-be-compressed data, correspondingly, the inverse processing is first performing inverse mapping processing, and then performing inverse translation processing and inverse stretching processing. In still another possible implementation, if translation processing is first performed, then stretching processing is performed, and finally mapping processing is performed on the to-be-compressed data, correspondingly, the inverse processing is first performing inverse mapping processing, and then performing inverse stretching processing and inverse translation processing. It should be understood that a formula used during inverse stretching processing is a mathematical inverse operation of a formula used during stretching processing, and a formula used during inverse translation processing is a mathematical inverse operation of a formula used during translation processing.

For example, the inverse mapping processing may be: obtaining the inverse function of the cumulative distribution function corresponding to the Gaussian distribution model based on the parameters corresponding to the Gaussian distribution model, and performing mapping processing on the compressed data corresponding to the Gaussian distribution model by using the inverse function.

The method for determining the target compressed data based on the target data distribution model in S202 may be further the following several methods:

In a possible implementation, when a difference obtained by subtracting the loss between the first decompressed data corresponding to the target data distribution model and the to-be-compressed data from a loss between second decompressed data and the to-be-compressed data is greater than 0 and greater than or equal to a preset threshold, the first compressed data corresponding to the target data distribution model is determined as the target compressed data, where the second decompressed data is obtained by performing decompression processing on second compressed data, the second compressed data is obtained by performing compression processing on the to-be-compressed data based on a second uniform quantizer, and the second uniform quantizer has same compression precision as the first uniform quantizer.

It should be understood that the transmit end may generate the second uniform quantizer in a given interval based on the to-be-compressed data. The given interval is determined by a largest value and a smallest value in the to-be-compressed data. For example, if the largest value in the to-be-compressed data is 0.974, and the smallest value is 0.012, the interval of the second uniform quantizer is [0.012, 0.974].

It should be understood that the preset threshold may be preset by the transmit end in advance. For example, the preset threshold may be 0.0002.

That the difference obtained by subtracting the loss between the first decompressed data corresponding to the target data distribution model and the to-be-compressed data from the loss between the second decompressed data and the to-be-compressed data is greater than 0 indicates that the loss between the second decompressed data and the to-be-compressed data is greater than the loss between the first decompressed data corresponding to the target data distribution model and the to-be-compressed data, and that the difference is greater than or equal to the preset threshold indicates that the loss between the second decompressed data and the to-be-compressed data is much greater than the loss between the first decompressed data corresponding to the target data distribution model and the to-be-compressed data, and the loss between the first decompressed data corresponding to the target data distribution model and the to-be-compressed data is relatively small. Therefore, the first compressed data corresponding to the target data distribution model is determined as the target compressed data.

In another possible implementation, when the difference obtained by subtracting the loss between the first decompressed data corresponding to the target data distribution model and the to-be-compressed data from the loss between the second decompressed data and the to-be-compressed data is less than 0 or the difference is greater than 0 and less than the preset threshold, the second compressed data is determined as the target compressed data.

That the difference obtained by subtracting the loss between the first decompressed data corresponding to the target data distribution model and the to-be-compressed data from the loss between the second decompressed data and the to-be-compressed data is less than 0 indicates that the loss between the second decompressed data and the to-be-compressed data is relatively small. Therefore, the second compressed data is determined as the target compressed data. That the difference obtained by subtracting the loss between the first decompressed data corresponding to the target data distribution model and the to-be-compressed data from the loss between the second decompressed data and the to-be-compressed data is greater than 0 and less than the preset threshold indicates that the loss between the first decompressed data corresponding to the target data distribution model and the to-be-compressed data is smaller but is not much smaller than the loss between the second decompressed data and the to-be-compressed data. Therefore, the second compressed data may still be determined as the target compressed data.

In another possible implementation, when the difference is less than 0 or the difference is greater than 0 and less than the preset threshold, the parameters of the target data distribution model are adjusted based on prior parameters; and compression processing is performed on the to-be-compressed data by using the target data distribution model based on the adjusted parameters, to obtain the target compressed data.

It should be understood that the prior parameters are sent by the receive end. For example, the prior parameters may be the parameters corresponding to the Gaussian distribution model: the mean and the variance.

For example, the method for adjusting the parameters of the target data distribution model based on the prior parameters, and performing compression processing on the to-be-compressed data by using the target data distribution model based on the adjusted parameters, to obtain the target compressed data may be: The receive end adjusts the parameters of the target data distribution model based on the received prior parameters, performs compression processing on the to-be-compressed data based on the adjusted parameters of the target data distribution model and the first uniform quantizer to obtain third compressed data corresponding to the target data distribution model, performs decompression processing on the third compressed data corresponding to the target data distribution model to obtain third decompressed data corresponding to the target data distribution model, and calculates a loss between the third decompressed data corresponding to the target data distribution model and the to-be-compressed data. The parameters of the target data distribution model may be adjusted for a plurality of times. When a parameter (variance) of the target data distribution model remains unchanged, a parameter (mean) is adjusted through bisection search, where is a parameter adjustment range is (2μₑₛₜμₚ, μₚ), μₑₛₜ is a mean corresponding to the target data distribution model before the parameter is adjusted, and μₚ is a prior parameter. Each time the parameters of the target data distribution model are adjusted, a corresponding loss may be calculated. After the parameters are adjusted for a plurality of times, a plurality of corresponding losses may be obtained. The parameters corresponding to the smallest loss are determined as the parameters of the target data distribution model, and the corresponding third compressed data obtained based on the parameters is determined as the target compressed data.

Optionally, a quantity of times of adjustment may be preset. For example, the quantity of times of adjustment may be preset to 50. A time spent in adjusting the parameters may be preset. For example, the time is preset to two seconds, and within the two seconds, the transmit end may perform parameter adjustment for 20 times.

It should be further understood that after adjusting the parameters corresponding to the target data distribution model, the transmit end sends, to the receive end, the adjusted parameters corresponding to the target data distribution model.

In another possible implementation, the transmit end may adjust the parameters of the target data distribution model based on the prior parameters without determining a value of the difference; and perform compression processing on the to-be-compressed data by using the target data distribution model based on the adjusted parameters, to obtain the target compressed data.

It should be understood that the method in which the transmit end may adjust the parameters of the target data distribution model based on the prior parameters without determining the value of the difference, and perform compression processing on the to-be-compressed data by using the target data distribution model based on the adjusted parameters, to obtain the target compressed data is the same as the foregoing method in which when the difference is less than 0 or the difference is greater than 0 and less than the preset threshold, the parameters of the target data distribution model are adjusted based on the prior parameters, and compression processing is performed on the to-be-compressed data by using the target data distribution model based on the adjusted parameters, to obtain the target compressed data.

Further, performing compression processing on the to-be-compressed data by using the target data distribution model based on the adjusted parameters, to obtain the target compressed data includes: performing compression processing on the to-be-compressed data by using the target data distribution model based on the adjusted parameters, to obtain the corresponding third compressed data, performing decompression processing on the third compressed data, to obtain the third decompressed data, and when a difference obtained by subtracting the loss between the third decompressed data corresponding to the target data distribution model and the to-be-compressed data from the loss between the second decompressed data and the to-be-compressed data is greater than 0 and greater than or equal to a preset threshold, determining the third compressed data as the target compressed data.

That the difference obtained by subtracting the loss between the third decompressed data corresponding to the target data distribution model and the to-be-compressed data from the loss between the second decompressed data and the to-be-compressed data is greater than 0 indicates that the loss between the third decompressed data and the to-be-compressed data is less than the loss between the second decompressed data and the to-be-compressed data, and that the difference is greater than or equal to the preset threshold indicates that the loss between the third decompressed data and the to-be-compressed data is much less than the loss between the second decompressed data and the to-be-compressed data. In this case, the third compressed data is determined as the target compressed data.

Optionally, when the difference obtained by subtracting the loss between the third decompressed data corresponding to the target data distribution model and the to-be-compressed data from the loss between the second decompressed data and the to-be-compressed data is less than 0 or the difference is greater than 0 and less than the preset threshold, the second compressed data is determined as the target compressed data.

That the difference obtained by subtracting the loss between the third decompressed data corresponding to the target data distribution model and the to-be-compressed data from the loss between the second decompressed data and the to-be-compressed data is less than 0 indicates that the loss between the second decompressed data and the to-be-compressed data is relatively small. That the difference is greater than 0 and less than the preset threshold indicates that the loss between the second decompressed data and the to-be-compressed data is greater but is not much greater than the loss between the third decompressed data corresponding to the target data distribution model and the to-be-compressed data. In the two cases, the second compressed data may be determined as the target compressed data.

Optionally, the foregoing method further includes: sending second information to the receive end, where the second information indicates parameters of the to-be-compressed data and the target data distribution model; and receiving third information from the receive end, where the third information includes the prior parameters.

It should be understood that the parameters of the to-be-compressed data may be location information of the to-be-compressed data. For example, the to-be-compressed data (data in a neural network model) is located at a second layer in the neural network model.

For example, the target data distribution model is the Gaussian distribution model.

It should be understood that the prior parameters are prior parameters corresponding to the target data distribution model. For example, the target data distribution model is the Gaussian distribution model, and the prior parameters are: variance (0.2), and mean: (0).

In an optional embodiment, before separately performing the compression processing on the to-be-compressed data based on the plurality of data distribution models and the first uniform quantizer, the method further includes: sending fourth information to the receive end, where the fourth information is used to query compression precision of the to-be-compressed data; and receiving fifth information from the receive end, where the fifth information indicates the compression precision of the to-be-compressed data.

It should be understood that the transmit end sends the fourth information to the receive end, where the fourth information carries a type and a data amount that are of the to-be-compressed data. Correspondingly, the receive end receives the fourth information, queries, based on the type and the data amount that are of the to-be-compressed data and that are carried in the fourth information, the compression precision corresponding to the data of the type and the data amount, and sends the compression precision to the transmit end. Processed data of the receive end may be data sent by the transmit end, or may be data sent by another device. This is not limited in this embodiment of this application.

It should be further understood that the transmit end may select a uniform quantizer based on the compression precision from the receive end, so that compression precision of compressed data obtained after the to-be-compressed data is compressed by using the selected quantizer is the same as the compression precision in the fifth information from the receive end.

In an optional embodiment, that the receive end performs decompression processing on the target compressed data based on the first information to obtain the target decompressed data in S204 includes: performing inverse processing on the target compressed data by using the target data distribution model based on the parameters corresponding to the target data distribution model, to obtain the target decompressed data, where the inverse processing includes inverse translation processing and/or inverse stretching processing, and inverse mapping processing.

It should be understood that the inverse processing may be in the following several cases: In a possible implementation, if translation processing is first performed and then mapping processing is performed on the to-be-compressed data, correspondingly, the inverse processing is first performing inverse mapping processing and then performing inverse translation processing on the target compressed data. In another possible implementation, if stretching processing is first performed and then mapping processing is performed on the to-be-compressed data, correspondingly, the inverse processing is first performing inverse mapping processing and then performing inverse stretching processing on the target compressed data. In another possible implementation, if stretching processing is first performed, then translation processing is performed, and finally mapping processing is performed on the to-be-compressed data, correspondingly, the inverse processing is first performing inverse mapping processing, and then performing inverse translation processing and inverse stretching processing on the target compressed data. In still another possible implementation, if translation processing is first performed, then stretching processing is performed, and finally mapping processing is performed on the to-be-compressed data, correspondingly, the inverse processing is first performing inverse mapping processing, and then performing inverse stretching processing and inverse translation processing on the target compressed data. It should be understood that a formula used during inverse stretching processing is a mathematical inverse operation of a formula used during stretching processing, and a formula used during inverse translation processing is a mathematical inverse operation of a formula used during translation processing.

For example, the inverse mapping processing may be: obtaining the inverse function of the cumulative distribution function corresponding to the Gaussian distribution model based on the parameters corresponding to the Gaussian distribution model, and performing mapping processing on the compressed data corresponding to the Gaussian distribution model by using the inverse function.

The following uses non-uniform to-be-compressed data D₁ as an example to describe this embodiment in detail.

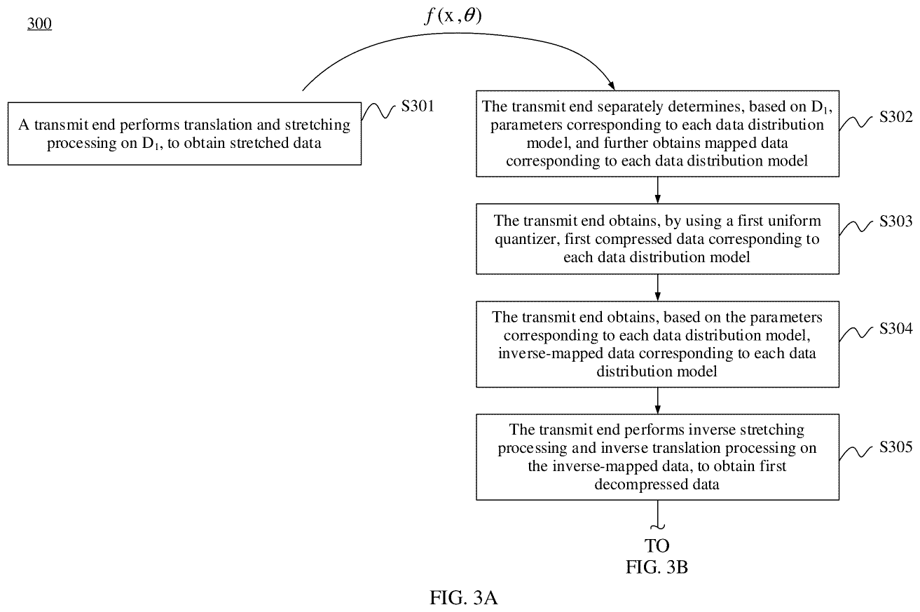

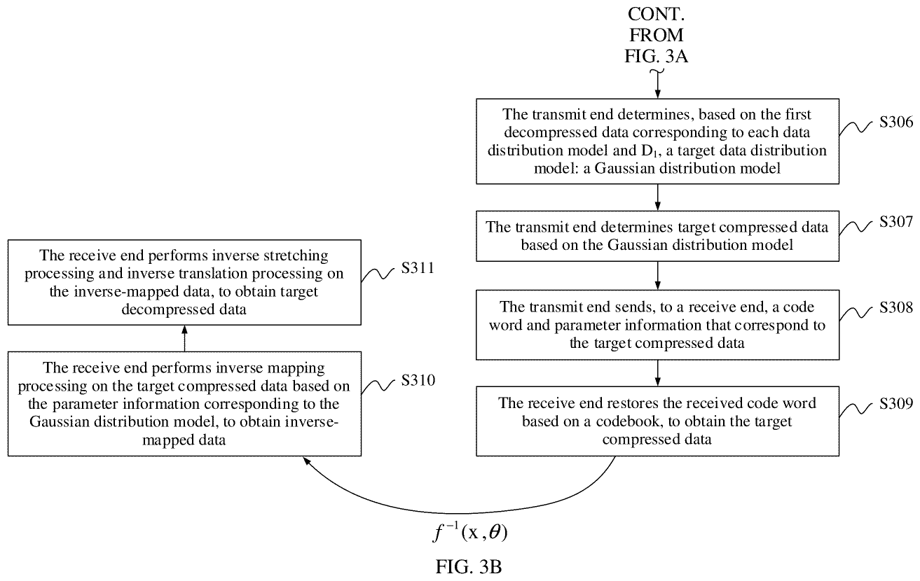

FIG. 3A and FIG. 3B show a schematic flowchart of another example data transmission method 300 according to an embodiment of this application. The method 300 includes the following steps.

S301: A transmit end performs translation and stretching processing on non-uniform to-be-compressed data D₁, to obtain stretched data, namely, preliminarily processed data, where the preliminarily processed data is in a range [0, 1].

S302: The transmit end separately determines, based on the non-uniform to-be-compressed data D₁, parameters corresponding to each data distribution model, and performs mapping processing on the preliminarily processed data by using a cumulative distribution function ƒ(x,θ₁) corresponding to each data distribution model, to obtain mapped data corresponding to each data distribution model, where the mapped data corresponding to each data distribution model is approximately uniformly distributed in the range [0, 1].

It should be understood that θ₁ in the cumulative distribution function ƒ(x,θ₁) is the parameters corresponding to the data distribution model. For example, if the data distribution model is a Gaussian distribution model, θ₁ is a mean 1 and a variance 1.

S303: The transmit end separately performs, by using a first uniform quantizer, quantization processing on the mapped data corresponding to each data distribution model, to obtain first compressed data corresponding to each data distribution model.

S304: The transmit end separately performs, by using an inverse function ƒ⁻¹(x,θ₁) of the cumulative distribution function corresponding to each data distribution model based on the parameters corresponding to each data distribution model, inverse mapping on the first compressed data corresponding to each data distribution type, to obtain inverse-mapped data corresponding to each data distribution model.

It should be understood that, if the parameters corresponding to each data distribution model are known, the inverse function of the cumulative distribution function corresponding to each data distribution model can be obtained.

S305: The transmit end performs inverse stretching processing and inverse translation processing on the inverse-mapped data, to obtain first decompressed data.

S306: The transmit end determines, based on the first decompressed data corresponding to each data distribution model and the non-uniform to-be-compressed data D₁, a target data distribution model: the Gaussian distribution model from the plurality of data distribution models, where in the plurality of data distribution models, a loss between the first decompressed data corresponding to the Gaussian distribution model and the non-uniform to-be-compressed data D₁ is the smallest.

It should be understood that this embodiment is described only by using an example in which the target data distribution model is the Gaussian distribution model. The target data distribution model may alternatively be another model, for example, a Laplace distribution model and a Beta distribution model. This is not limited in this application.

S307: The transmit end determines target compressed data based on the Gaussian distribution model.

S308: The transmit end sends, to a receive end, a code word and parameter information that correspond to the target compressed data, where the parameter information includes information indicating the Gaussian distribution model: a mean 1 and a variance 1. Correspondingly, the receive end receives the code word and the parameter information that correspond to the target compressed data and that are from the transmit end.

It should be understood that there is a correspondence between data in the target compressed data and a code word, and the correspondence is recorded in a codebook. For example, the target compressed data is 0.2, and the code word corresponding to the target compressed data is 2. Both the transmit end and the receive end store the codebook.

S309: The receive end restores the received code word based on the codebook, to obtain the target compressed data.

S310: The receive end obtains, based on the mean 1 and the variance 1 that correspond to the Gaussian distribution model, the inverse function ƒ⁻¹(x,θ₁) of the cumulative distribution function corresponding to the Gaussian distribution model, and performs inverse mapping processing on the target compressed data, to obtain inverse-mapped data.

S311: The receive end performs inverse stretching processing and inverse translation processing on the inverse-mapped data, to obtain target decompressed data.

In the foregoing method, the data distribution model corresponding to the smallest loss is determined as the target data distribution model, and the compressed data corresponding to the target model is determined as the target compressed data, so that the receive end finally receives the compressed data with the smallest loss. In addition, the target model is used to process the to-be-compressed data, so that processed data is approximately uniformly distributed, and then the uniform quantizer is used for quantization, to avoid a quantization loss caused by compressing the non-uniform to-be-compressed data by using the uniform quantizer. This method helps reduce quantization loss in a data transmission process, and reduce distortion between the data obtained by the receive end through decompression and data of the transmit end, so that the data obtained by the receive end is more accurate, thereby facilitating further processing or use of the data by the receive end.

The following uses non-uniform to-be-compressed data D₂ as an example to describe this embodiment in detail.

FIG. 4A, FIG. 4B, FIG. 4C, and FIG. 4D show a schematic flowchart of another example data transmission method 400 according to an embodiment of this application. The method 400 includes the following steps.

S401: A transmit end sends query information to a receive end, where the query information carries a type and a data amount that are of the non-uniform to-be-compressed data D₂, and the query information is used to query compression precision of the non-uniform to-be-compressed data D₂. Correspondingly, the receive end receives the query information from the transmit end.

S402: The receive end queries, based on the query information and the type and the data amount that are of the non-uniform to-be-compressed data D₂ and that are carried in the query information, the compression precision corresponding to the data of the type and the data amount.

It should be understood that there is a correspondence between the compression precision and the type of the to-be-compressed data and the amount of the to-be-compressed data.

S403: The receive end sends response information to the transmit end, where the response information includes the compression precision of the non-uniform to-be-compressed data D₂. Correspondingly, the transmit end receives the response message.

S404: The transmit end performs translation processing on the non-uniform to-be-compressed data D₂ by using the following formula (1), and performs stretching processing by using the following formula (2), to obtain stretched data, namely, preliminarily processed data, where the preliminarily processed data is in a range [0, 1].

$$= {D}_{i} + \vert min {D}_{i} \vert \qquad ( 1 )$$

Dᵢ an i^{th} piece of data in the to-be-compressed data D₂, i is an index of the to-be-compressed data, min Dᵢ is the smallest piece of data in the to-be-compressed data, and [symbol] ᵢ is data obtained after the i^{th} piece of data in the to-be-compressed data D₂ is translated.

$${x}_{i} = \frac{max \vert \vert}{} \qquad ( 2 )$$

[symbol] is the data obtained after the i^{th} piece of data in the to-be-compressed data D₂ is translated, max | [symbol] | is data with a largest absolute value in the translated data corresponding to the to-be-compressed data D₂, and xᵢ is data obtained after the i^{th} piece of data in the to-be-compressed data D₂ is preliminarily processed.

S405: The transmit end separately determines, by using a Bayesian inference algorithm based on the non-uniform to-be-compressed data D₂, parameters corresponding to each data distribution model, and performs mapping processing on the preliminarily processed data by using a cumulative distribution function ƒ(x,θ₂) corresponding to each data distribution model, to obtain mapped data corresponding to each data distribution model, where the mapped data corresponding to each data distribution model is approximately uniformly distributed in the range [0, 1].

It should be understood that θ₂ in the cumulative distribution function ƒ(x,θ₂) is the parameters corresponding to the data distribution model. For example, if the data distribution model is a Gaussian distribution model, θ₂ is a mean 2 and a variance 2.

S406: The transmit end separately performs, by using a first uniform quantizer, quantization processing on the mapped data corresponding to each data distribution model, to obtain first compressed data corresponding to each data distribution model, where compression precision corresponding to the first uniform quantizer is the same as the compression precision in the response message in S402.

S407: The transmit end separately performs, by using an inverse function ƒ⁻¹(x,θ₂) of the cumulative distribution function corresponding to each data distribution model based on the parameters corresponding to each data distribution model, inverse mapping on the first compressed data corresponding to each data distribution type, to obtain inverse-mapped data corresponding to each data distribution model.

S408: The transmit end performs inverse stretching processing on the inverse-mapped data by using the following formula (3), and performs inverse translation processing by using the following formula (4), to obtain first decompressed data corresponding to each data distribution model.

$$= {\hat{x}}_{i} \cdot max \vert \vert \qquad ( 3 )$$

Based on the foregoing S404, max(Dᵢ+|min Dᵢ|) may be obtained, where max(Dᵢ+|min Dᵢ|) is max | [symbol] |.

xᵢ is an i^{th} piece of data in the inverse-mapped data, max(Dᵢ+|min Dᵢ|) is the largest value in data obtained after the to-be-compressed data D₂ is translated, and [symbol] is data obtained after the i^{th} piece of data in the mapped data is inversely stretched.

$${D}_{i} = - \vert min {D}_{i} \vert \qquad ( 4 )$$

[symbol] is data obtained after the i^{th} piece of data in the mapped data is inversely stretched, Dᵢ is the i^{th} piece of data in the to-be-compressed data D₂, i is the index of the to-be-compressed data, and min Dᵢ is the smallest piece of data in the to-be-compressed data.

S409: The transmit end determines, based on the first decompressed data corresponding to each data distribution model and the non-uniform to-be-compressed data D₂, a target data distribution model: the Gaussian distribution model from the plurality of data distribution models, where in the plurality of data distribution models, a loss between the first decompressed data corresponding to the Gaussian distribution model and the non-uniform to-be-compressed data D₂ is the smallest.

S410: The transmit end generates a second uniform quantizer in a given interval based on the non-uniform to-be-compressed data, and performs compression processing on the non-uniform to-be-compressed data D₂ based on the second uniform quantizer, to obtain second compressed data, where compression precision of the second uniform quantizer is the same as the compression precision of the first uniform quantizer.

It should be understood that the given interval is determined by a largest value and a smallest value in the non-uniform to-be-compressed data D₂.

S411: The transmit end performs decompression processing on the second compressed data, to obtain second decompressed data.

S412: The transmit end determines a loss between the second decompressed data and the non-uniform to-be-compressed data D₂.

S413: The transmit end calculates a difference obtained by subtracting a loss between the first decompressed data corresponding to the Gaussian distribution model and the non-uniform to-be-compressed data D₂ from the loss between the second decompressed data and the non-uniform to-be-compressed data D₂, where the difference is less than 0.

S414: The transmit end sends indication information to the receive end, where the indication information indicates that the non-uniform to-be-compressed data is data at the second layer of a neural network model and indicates the Gaussian distribution model. Correspondingly, the receive end receives the indication information.

S415: The receive end queries, in processed data based on the indication information from the transmit end, parameters that belong to the Gaussian distribution model and that are of the Gaussian distribution model corresponding to the data located at the second layer in the neural network model: meanₚᵣᵢₒᵣ and varianceₚᵣᵢₒᵣ, where the parameters are also referred to as prior parameters.

S416: The receive end sends the prior parameters to the transmit end. Correspondingly, the transmit end receives the prior parameters: meanₚᵣᵢₒᵣ and varianceₚᵣᵢₒᵣ.

S417: The transmit end adjusts the parameters of the Gaussian distribution model based on the prior parameters, and performs mapping processing on the preliminarily processed data based on the adjusted parameters (a mean 3 and a variance 3) by using the cumulative distribution function ƒ(x,θ₃) corresponding to the Gaussian distribution model, to obtain mapped data corresponding to the Gaussian distribution model with adjusted parameters.

It should be understood that, when the variance of the Gaussian distribution model remains unchanged, an adjustment range of the mean of the Gaussian distribution model is (2μₑₛₜ−μₚ, μₚ), where μₑₛₜ is a mean corresponding to the target data distribution model before the parameter is adjusted, and μₚ is meanₚᵣᵢₒᵣ. It should be further understood that θ₃ in ƒ(x,θ₃) is: a mean 3 and a variance 3.

S418: The transmit end performs, by using the first uniform quantizer, quantization processing on the mapped data corresponding to the Gaussian distribution model with adjusted parameters, to obtain third compressed data corresponding to the Gaussian distribution model with adjusted parameters.

S419: The transmit end performs inverse mapping on the third compressed data based on the adjusted parameters of the Gaussian distribution model by using the inverse function ƒ⁻¹(x,θ₃) of the cumulative distribution function corresponding to the Gaussian distribution model, to obtain inverse-mapped data.

S420: The transmit end performs inverse stretching processing and inverse translation processing on the inverse-mapped data, to obtain third decompressed data.

S421: The transmit end determines a loss between the third decompressed data and the non-uniform to-be-compressed data D₂.

S422: The transmit end adjusts the parameters of the Gaussian distribution model for 20 times based on S417 to S421, obtains a corresponding loss each time the parameters of the Gaussian distribution model are adjusted, and determines parameters corresponding to the smallest loss as final parameters (a mean 4 and a variance 4) of the Gaussian distribution model.

S423: The transmit end calculates a difference obtained by subtracting a loss between the third decompressed data corresponding to the final parameters of the Gaussian distribution model and the non-uniform to-be-compressed data D₂ from the loss between the second decompressed data and the non-uniform to-be-compressed data D₂, where the difference is greater than 0, and the transmit end determines the third compressed data corresponding to the final parameters of the Gaussian distribution model as target compressed data.

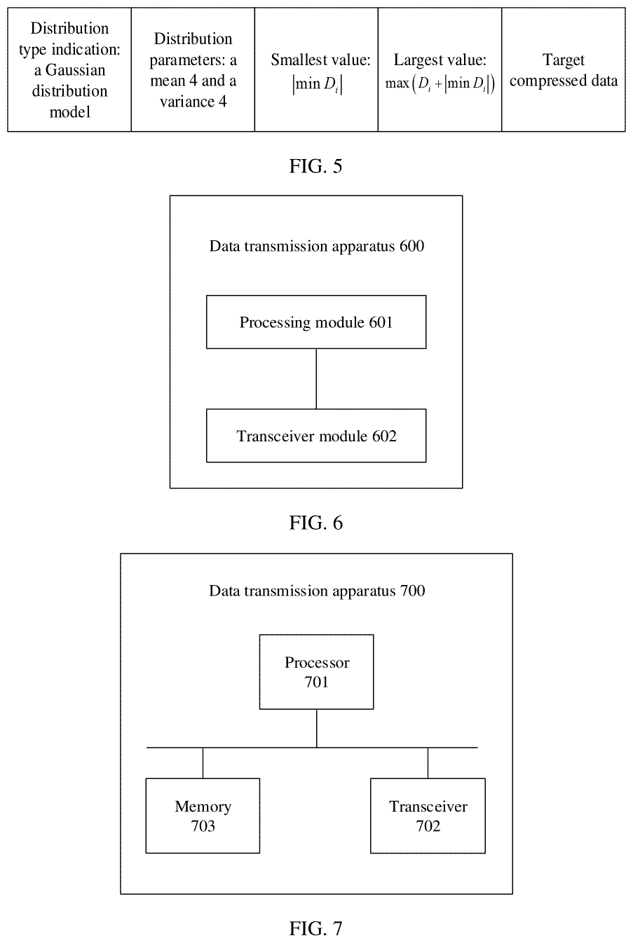

S424: The transmit end sends, to the receive end, the target compressed data and the parameter information that are shown in FIG. 5. The parameter information includes: a distribution type indication: a Gaussian distribution model; distribution parameters: the mean 4 and the variance 4; and the smallest value |min Dᵢ| and the largest value max(Dᵢ+|min Dᵢ|). Correspondingly, the receive end receives the target compressed data and the parameter information.

It should be understood that the distribution type indication is a target data distribution model indication. When sending the distribution type indication to the receive end, the transmit end may directly send the distribution type indication: the Gaussian distribution model, or may send a number corresponding to the Gaussian distribution model, for example, the distribution type indication: 1. The receive end may identify, based on the number 1, that a data distribution model corresponding to 1 is the Gaussian distribution model, and 1 occupies a limited quantity of bits. The distribution parameters are the adjusted parameters corresponding to the target data distribution model, |min Dᵢ| is an absolute value of the smallest piece of data in the to-be-compressed data, and max(Dᵢ+|min Dᵢ|) is the largest value in the data obtained after the to-be-compressed data is translated, and the values may be obtained in S404.

It should be further understood that the transmit end may directly send the target compressed data to the receive end, or may send a code word corresponding to the target compressed data to the receive end, and the receive end obtains the target compressed data based on the received code word by using a codebook. There is a correspondence between the code word and the target compressed data, and the code word and the target compressed data that have the correspondence are recorded in the codebook. Both the transmit end and the receive end have the codebook.

It should be understood that when the difference is less than 0, or the difference is greater than 0 and less than a preset threshold, the transmit end determines the second compressed data as the target compressed data.

S425: The receive end performs inverse mapping on the target compressed data based on the parameters (the mean 4 and the variance 4) of the Gaussian distribution model by using the inverse function ƒ⁻¹(x,θ₄) of the cumulative distribution function corresponding to the Gaussian distribution model, to obtain inverse-mapped data.

It should be understood that, θ₄ in ƒ⁻¹(x,θ₄) is: the mean 4 and the variance 4.

S426: The receive end performs inverse stretching processing and inverse translation processing on the inverse-mapped data based on |min Dᵢ| and max(Dᵢ+|min Dᵢ|) by using the formula (3) and the formula (4) in S408, to obtain target decompressed data.

It should be understood that sequence numbers of the foregoing processes do not mean execution sequences, and the execution sequences of the processes should be determined based on functions and internal logic of the processes.

The data transmission methods provided in embodiments of this application are described in detail above with reference to FIG. 2 to FIG. 5, and data transmission apparatuses provided in embodiments of this application are described in detail below with reference to FIG. 6 and FIG. 7.

FIG. 6 shows an example data transmission apparatus 600 according to an embodiment of this application. The apparatus 600 includes a processing module 601 and a transceiver module 602.

In a possible implementation, the apparatus 600 is configured to implement the steps corresponding to the transmit end in the method 200.

The processing module 601 is configured to: determine a target data distribution model from a plurality of data distribution models based on to-be-compressed data, the plurality of data distribution models, and a first uniform quantizer, where in the plurality of data distribution models, a loss between first decompressed data corresponding to the target data distribution model and the to-be-compressed data is the smallest; and determine target compressed data based on the target data distribution model; and the transceiver module 602 is configured to send the target compressed data and first information to a receive end, where the first information includes information indicating the target data distribution model.

Optionally, the processing module 601 is further configured to: separately perform compression processing on the to-be-compressed data based on the plurality of data distribution models and the first uniform quantizer, to obtain first compressed data corresponding to each data distribution model in the plurality of data distribution models; perform decompression processing on the first compressed data corresponding to each data distribution model, to obtain first decompressed data corresponding to each data distribution model; and determine the target data distribution model from the plurality of data distribution models based on the first decompressed data corresponding to each data distribution model and the to-be-compressed data.

Optionally, the processing module 601 is further configured to: separately determine, based on the to-be-compressed data, parameters corresponding to each data distribution model; separately perform mapping processing on the to-be-compressed data by using each data distribution model based on the parameters corresponding to each data distribution model, to obtain mapped data corresponding to each data distribution model, where the mapped data corresponding to each data distribution model is uniformly distributed within a preset interval range; and separately perform, by using the first uniform quantizer, quantization processing on the mapped data corresponding to each data distribution model, to obtain the first compressed data corresponding to each data distribution model.

Optionally, the first information further includes information indicating parameters corresponding to the target data distribution model.

Optionally, the processing module 601 is further configured to: perform preliminary processing on the to-be-compressed data, to obtain preliminarily processed data, where the preliminarily processed data is within the preset interval range, and the preliminary processing includes translation processing and/or stretching processing; and separately perform the mapping processing on the preliminarily processed data by using each data distribution model based on the parameters corresponding to each data distribution model, to obtain the mapped data corresponding to each data distribution model.

Optionally, the processing module 601 is further configured to separately perform, by using each data distribution model based on the parameters corresponding to each data distribution model, inverse processing on the first compressed data corresponding to each data distribution model, to obtain the first decompressed data corresponding to each data distribution model, where the inverse processing includes inverse translation processing and/or inverse stretching processing, and inverse mapping processing.

Optionally, the processing module 601 is further configured to: when a difference obtained by subtracting the loss between the first decompressed data corresponding to the target data distribution model and the to-be-compressed data from a loss between second decompressed data and the to-be-compressed data is greater than 0 and greater than or equal to a preset threshold, determine the first compressed data corresponding to the target data distribution model as the target compressed data, where the second decompressed data is obtained by performing decompression processing on second compressed data, the second compressed data is obtained by performing compression processing on the to-be-compressed data based on a second uniform quantizer, and the second uniform quantizer has same compression precision as the first uniform quantizer.

Optionally, the processing module 601 is further configured to: when the difference is less than 0 or the difference is greater than 0 and less than the preset threshold, adjust the parameters of the target data distribution model based on prior parameters; and perform compression processing on the to-be-compressed data by using the target data distribution model based on the adjusted parameters, to obtain the target compressed data.

Optionally, the transceiver module 602 is further configured to: send second information to the receive end, where the second information indicates parameters of the to-be-compressed data and the target data distribution model; and receive third information from the receive end, where the third information includes the prior parameters.

Optionally, the transceiver module 602 is further configured to: send fourth information to the receive end, where the fourth information is used to query compression precision of the to-be-compressed data; and receive fifth information from the receive end, where the fifth information indicates the compression precision of the to-be-compressed data.

In another possible implementation, the apparatus 600 is configured to implement the steps corresponding to the receive end in the method 200.

The transceiver module 602 is configured to receive target compressed data and first information from a transmit end, where the target compressed data is obtained by performing compression processing on to-be-compressed data by using a target data distribution model and a first uniform quantizer, and the first information includes information indicating the target data distribution model; and the processing module 601 is configured to perform decompression processing on the target compressed data based on the first information, to obtain target decompressed data.

Optionally, the first information further includes information indicating parameters corresponding to the target data distribution model.

Optionally, the processing module 601 is further configured to perform inverse processing on the target compressed data by using the target data distribution model based on the parameters corresponding to the target data distribution model, to obtain the target decompressed data, where the inverse processing includes inverse translation processing and/or inverse stretching processing, and inverse mapping processing.

Optionally, the transceiver module 602 is further configured to: receive second information from the transmit end, where the second information indicates parameters of the to-be-compressed data and the target data distribution model; and send third information to the transmit end, where the third information includes prior parameters of the target data distribution model.

Optionally, the transceiver module 602 is further configured to: receive fourth information from the transmit end, where the fourth information is used to query compression precision of the to-be-compressed data; and send fifth information to the transmit end, where the fifth information indicates the compression precision of the to-be-compressed data.

It should be understood that the apparatus 600 herein is represented in a form of a functional module. The term “module” herein may be an application specific integrated circuit (ASIC), an electronic circuit, a processor (for example, a shared processor, a dedicated processor, or a group processor) configured to execute one or more software or firmware programs, a memory, a merged logic circuit, and/or another appropriate component that supports the described function. In an optional example, a person skilled in the art may understand that, the apparatus 600 may be specifically the transmit end or the receive end in the foregoing embodiments, and may be configured to perform the procedures and/or steps corresponding to the transmit end or the receive end in the foregoing method embodiments.

The apparatus 600 has a function of implementing the corresponding steps performed by the transmit end or the receive end in the foregoing methods. The foregoing function may be implemented by hardware, or may be implemented by hardware executing corresponding software. The hardware or the software includes one or more modules corresponding to the function. For example, the transceiver module 602 may include a sending module and a receiving module. The sending module may be configured to implement the steps and/or procedures that are used for executing the sending action and that correspond to the transceiver module, and the receiving module may be configured to implement the steps and/or procedures that are used for executing the receiving action and that correspond to the transceiver module. The sending module may be replaced by a transmitter, and the receiving module may be replaced by a receiver, to respectively perform sending and receiving operations and related processing operations in the method embodiments.

In this embodiment, the data transmission apparatus 600 in FIG. 6 may alternatively be a chip or a chip system, for example, a system on chip (SOC). Correspondingly, the processing module 601 and the transceiver module 602 may be a transceiver circuit of the chip. This is not limited herein.

FIG. 7 shows another example data transmission apparatus 700 according to an embodiment of this application. The data transmission apparatus 700 includes a processor 701, a transceiver 702, and a memory 703. The processor 701, the transceiver 702, and the memory 703 communicate with each other through an internal connection path. The memory 703 is configured to store instruction. The processor 701 is configured to execute the instructions stored in the memory 703, to control the transceiver 702 to send a signal and/or receive a signal.

It should be understood that, the data transmission apparatus 700 may be specifically the transmit end or the receive end in the foregoing embodiments, and may be configured to perform the procedures and/or steps corresponding to the transmit end or the receive end in the foregoing method embodiments. Optionally, the memory 703 may include a read-only memory and a random access memory, and provide instructions and data for the processor 701. A part of the memory 703 may further include a non-volatile random access memory. For example, the memory 703 may further store information about a device type. The processor 701 may be configured to execute the instructions stored in the memory. When the processor 701 executes the instructions stored in the memory, the processor 701 is configured to perform the steps and/or procedures that are of the method embodiments and that correspond to the transmit end or the receive end. The transceiver 702 may include a transmitter and a receiver. The transmitter may be configured to implement the steps and/or procedures that are used for executing the sending action and that correspond to the transceiver, and the receiver may be configured to implement the steps and/or procedures that are used for executing the receiving action and that correspond to the transceiver.

It should be understood that, in this embodiment, the processor 701 may be a central processing unit (CPU), and the processor 701 may alternatively be another general-purpose processor, a digital signal processor (DSP), an application specific integrated circuit (ASIC), a field programmable gate array (FPGA) or another programmable logic device, a discrete gate or transistor logic device, a discrete hardware component, or the like. The general-purpose processor may be a microprocessor, or the processor may be any conventional processor or the like.

In an implementation process, the steps of the foregoing methods may be implemented by using a hardware integrated logic circuit in the processor, or by using instructions in a form of software. The steps of the methods disclosed with reference to embodiments of this application may be directly performed by a hardware processor, or may be performed by using a combination of hardware and software modules in the processor. The software module may be located in a mature storage medium in the art, such as a random access memory, a flash memory, a read-only memory, a programmable read-only memory, an electrically erasable programmable memory, or a register. The storage medium is located in the memory. The processor executes the instructions in the memory, and completes the steps of the foregoing methods in combination with hardware of the processor.

This application further provides a computer-readable storage medium. The computer-readable storage medium is configured to store a computer program, and the computer program is configured to implement the methods that are in the foregoing embodiments and that correspond to the transmit end or the receive end.

This application further provides a computer program product. The computer program product includes a computer program (which may also be referred to as code or an instruction). When the computer program is run on a computer, the computer may perform the methods that are shown in the foregoing embodiments and that correspond to the transmit end or the receive end.

A person of ordinary skill in the art may be aware that, in combination with the examples described in embodiments disclosed in this specification, modules and algorithm steps may be implemented by electronic hardware or a combination of computer software and electronic hardware. Whether the functions are performed by hardware or software depends on particular applications and design constraint conditions of the technical solutions. A person skilled in the art may use different methods to implement the described functions for each particular application, but it should not be considered that the implementation goes beyond the scope of this application.

It may be clearly understood by a person skilled in the art that, for the purpose of convenient and brief description, for detailed working processes of the foregoing systems, apparatuses, and modules, refer to corresponding processes in the foregoing method embodiments.

In the several embodiments provided in present disclosure, it should be understood that the disclosed systems, apparatuses, and methods may be implemented in other manners. For example, the apparatus embodiments described above are merely examples. For example, division into the modules is merely logic function division and may be other division during actual implementation. For example, a plurality of modules or components may be combined or integrated into another system, or some features may be ignored or not performed. In addition, the displayed or discussed mutual couplings or direct couplings or communication connections may be implemented through some interfaces. The indirect couplings or communication connections between the apparatuses or modules may be implemented in electronic, mechanical, or other forms.

The modules described as separate parts may or may not be physically separate, and parts displayed as modules may or may not be physical units, may be located in one position, or may be distributed on a plurality of network modules. Some or all of the units may be selected based on actual requirements to achieve the objectives of the solutions of embodiments.

In addition, functional units in embodiments of this application may be integrated into one processing module, each of the modules may exist alone physically, or two or more modules may be integrated into one module.

When the functions are implemented in the form of a software functional module and sold or used as an independent product, the functions may be stored in a computer-readable storage medium. Based on such an understanding, the technical solutions of this application essentially, or the part contributing to the conventional technology, or some of the technical solutions may be implemented in a form of a software product. The computer software product is stored in a storage medium, and includes several instructions for indicating a computer device (which may be a personal computer, a server, a network device, or the like) to perform all or some of the steps of the methods described in embodiments of this application. The foregoing storage medium includes various media that may store program code, such as a USB flash drive, a removable hard disk, a read-only memory (ROM), a random access memory (RAM), a magnetic disk, or an optical disc.

The foregoing descriptions are merely non-limiting examples of specific implementations and are not intended to limit the protection scope, which is intended to cover any variation or replacement readily determined by a person of ordinary skill in the art. Therefore, the claims shall define the protection scope.

1. A data transmission method, comprising:
selecting a target data distribution model from a plurality of data distribution models based on to-be-compressed data, the plurality of data distribution models, and a first uniform quantizer, wherein, among the plurality of data distribution models, a loss between first decompressed data corresponding to the target data distribution model and the to-be-compressed data is the smallest;
determining target compressed data based on the target data distribution model; and
transmitting the target compressed data and first information to a receive end, wherein the first information comprises information identifying the target data distribution model.

2. The method according to claim 1, wherein selecting the target data distribution model from the plurality of data distribution models based on the to-be-compressed data, the plurality of data distribution models, and the first uniform quantizer comprises:
separately compressing the to-be-compressed data based on the plurality of data distribution models and the first uniform quantizer, to obtain first compressed data corresponding to each data distribution model in the plurality of data distribution models;
decompressing the first compressed data corresponding to each data distribution model, to obtain first decompressed data corresponding to each data distribution model; and
selecting the target data distribution model from the plurality of data distribution models based on the first decompressed data corresponding to each data distribution model and the to-be-compressed data.

3. The method according to claim 2, wherein separately compressing the to-be-compressed data based on the plurality of data distribution models and the first uniform quantizer, to obtain the first compressed data corresponding to each data distribution model comprises:
separately determining, based on the to-be-compressed data, parameters corresponding to each data distribution model;
separately performing mapping processing on the to-be-compressed data using each data distribution model based on the parameters corresponding to each data distribution model, to obtain mapped data corresponding to each data distribution model, wherein the mapped data corresponding to each data distribution model is uniformly distributed within a preset interval range; and
separately performing, using the first uniform quantizer, quantization processing on the mapped data corresponding to each data distribution model, to obtain the first compressed data corresponding to each data distribution model.

4. The method according to claim 3, wherein the first information further comprises information indicating parameters corresponding to the target data distribution model.

5. The method according to claim 3, wherein separately performing the mapping processing on the to-be-compressed data using each data distribution model based on the parameters corresponding to each data distribution model, to obtain the mapped data corresponding to each data distribution model, further comprises:
performing preliminary processing on the to-be-compressed data, to obtain preliminarily processed data, wherein the preliminarily processed data is within the preset interval range, and the preliminary processing comprises translation processing and/or stretching processing; and
separately performing the mapping processing on the preliminarily processed data using each data distribution model based on the parameters corresponding to each data distribution model, to obtain the mapped data corresponding to each data distribution model.

6. The method according to claim 5, wherein decompressing the first compressed data corresponding to each data distribution model, to obtain the first decompressed data corresponding to each data distribution model comprises:
separately performing, using each data distribution model based on the parameters corresponding to each data distribution model, inverse processing on the first compressed data corresponding to each data distribution model, to obtain the first decompressed data corresponding to each data distribution model, wherein the inverse processing comprises 1) inverse translation processing and/or inverse stretching processing, and 2) inverse mapping processing.

7. The method according to claim 1, wherein determining the target compressed data based on the target data distribution model comprises:
when a difference between (1) the loss between the first decompressed data corresponding to the target data distribution model and the to-be-compressed data and (2) a loss between second decompressed data and the to-be-compressed data is greater than 0 and greater than or equal to a preset threshold, determining first compressed data corresponding to the target data distribution model as the target compressed data, wherein the second decompressed data is obtained by decompressing second compressed data, the second compressed data is obtained by compressing the to-be-compressed data based on a second uniform quantizer, and the second uniform quantizer has same compression precision as the first uniform quantizer.

8. The method according to claim 7, wherein determining the target compressed data based on the target data distribution model comprises:
when the difference is less than 0 or the difference is greater than 0 and less than the preset threshold, adjusting parameters of the target data distribution model based on prior parameters; and
compressing the to-be-compressed data using the target data distribution model based on the adjusted parameters, to obtain the target compressed data.

9. The method according to claim 8, further comprising:
sending second information to the receive end, wherein the second information indicates parameters of the to-be-compressed data and the target data distribution model; and
receiving third information from the receive end, wherein the third information comprises the prior parameters.

10. The method according to claim 2, wherein before separately compressing the to-be-compressed data based on the plurality of data distribution models and the first uniform quantizer, the method further comprises:
sending fourth information to the receive end to query compression precision of the to-be-compressed data; and
receiving fifth information from the receive end, wherein the fifth information indicates the compression precision of the to-be-compressed data.

11. A data transmission method, comprising:
receiving target compressed data and first information from a transmit end, wherein the target compressed data is obtained by compressing to-be-compressed data using a target data distribution model and a first uniform quantizer, and the first information comprises information identifying the target data distribution model; and
decompressing the target compressed data based on the first information, to obtain target decompressed data.

12. The method according to claim 11, wherein the first information further comprises information indicating parameters corresponding to the target data distribution model.

13. The method according to claim 12, wherein decompressing the target compressed data based on the first information, to obtain the target decompressed data comprises:
performing inverse processing on the target compressed data using the target data distribution model based on the parameters corresponding to the target data distribution model, to obtain the target decompressed data, wherein the inverse processing comprises 1) inverse translation processing and/or inverse stretching processing, and 2) inverse mapping processing.

14. The method according to claim 11, wherein before receiving the target compressed data and the first information from the transmit end, the method further comprises:
receiving second information from the transmit end, wherein the second information indicates parameters of the to-be-compressed data and the target data distribution model; and
sending third information to the transmit end, wherein the third information comprises prior parameters of the target data distribution model.

15. The method according to claim 11, wherein before receiving the target compressed data and the first information from the transmit end, the method further comprises:
receiving fourth information from the transmit end to query compression precision of the to-be-compressed data; and
sending fifth information to the transmit end, wherein the fifth information indicates the compression precision of the to-be-compressed data.

16. A data transmission apparatus, comprising:
a processor, configured to: select a target data distribution model from a plurality of data distribution models based on to-be-compressed data, the plurality of data distribution models, and a first uniform quantizer, wherein, among the plurality of data distribution models, a loss between first decompressed data corresponding to the target data distribution model and the to-be-compressed data is the smallest; and generate target compressed data based on the target data distribution model; and
a transceiver, configured to transmit the target compressed data and first information to a receive end, wherein the first information comprises information identifying the target data distribution model.

17. The apparatus according to claim 16, wherein the processor is further configured to:
separately compress the to-be-compressed data based on the plurality of data distribution models and the first uniform quantizer, to obtain first compressed data corresponding to each data distribution model in the plurality of data distribution models;
decompress the first compressed data corresponding to each data distribution model, to obtain first decompressed data corresponding to each data distribution model; and
select the target data distribution model from the plurality of data distribution models based on the first decompressed data corresponding to each data distribution model and the to-be-compressed data.

18. The apparatus according to claim 17, wherein the processor is further configured to:
separately determine, based on the to-be-compressed data, parameters corresponding to each data distribution model;
separately perform mapping processing on the to-be-compressed data using each data distribution model based on the parameters corresponding to each data distribution model, to obtain mapped data corresponding to each data distribution model, wherein the mapped data corresponding to each data distribution model is uniformly distributed within a preset interval range; and
separately perform, using the first uniform quantizer, quantization processing on the mapped data corresponding to each data distribution model, to obtain the first compressed data corresponding to each data distribution model.

19. The apparatus according to claim 18, wherein the first information further comprises information indicating parameters corresponding to the target data distribution model.

20. The apparatus according to claim 18, wherein the processor is further configured to:
perform preliminary processing on the to-be-compressed data, to obtain preliminarily processed data, wherein the preliminarily processed data is within the preset interval range, and the preliminary processing comprises translation processing and/or stretching processing; and
separately perform the mapping processing on the preliminarily processed data using each data distribution model based on the parameters corresponding to each data distribution model, to obtain the mapped data corresponding to each data distribution model.
